(19) United States
(12) Patent Application Publication
(10) Pub. No.: US 2023/0345801 A1
(43) Pub. Date: Oct. 26, 2023

(54) DISPLAY DEVICE

(71) Applicant: SAMSUNG DISPLAY CO., LTD., YONGIN-SI (KR)

(72) Inventors: MINJUN JO, Yongin-si (KR); JAE KYUNG GO, Yongin-si (KR); YONG-JUN PARK, Yongin-si (KR); HAELIN YONG, Yongin-si (KR); JINHWAN JEON, Yongin-si (KR); KITAEK JEONG, Yongin-si (KR); YOUNG SEO CHOI, Yongin-si (KR); HAERI CHOI, Yongin-si (KR)

(21) Appl. No.: 18/193,845

(22) Filed: Mar. 31, 2023

(30) Foreign Application Priority Data
Apr. 20, 2022 (KR) 10-2022-0049031

(51) Int. Cl. H10K 59/80

(52) U.S. Cl. CPC H10K 59/873; H10K 59/12

(57) ABSTRACT

Provided is a display device including a first substrate including an active region and a peripheral region, a circuit element layer on the first substrate and including insulating layers and a transistor, a display element layer on the circuit element layer and including a pixel-defining layer having an opening defined therein, a light-emitting element including a first electrode exposed by the opening, a second electrode, and a light-emitting layer disposed between the first and second electrodes, and a partition wall overlapping the peripheral region, a second substrate disposed on the display element layer, a sealing member overlapping the peripheral region and defining an inner space, and a filling member disposed in the inner space, wherein a recessed portion overlapping the peripheral region is defined in a rear surface of the second substrate facing the display element layer, and a part of the filling member is disposed in the recessed portion.

### CROSS-REFERENCE TO RELATED APPLICATIONS

This U.S. non-provisional patent application claims priority under 35 U.S.C. § 119 to Korean Patent Application No. 10-2022-0049031, filed on Apr. 20, 2022, in the Korean Intellectual Property Office, the entire contents of which are herein incorporated by reference.

### TECHNICAL FIELD

The present inventive concept relates to a display device, and more particularly, to a display device in which a bonding force between a sensing panel and a display panel is enhanced, and which has enhanced display quality.

### DISCUSSION OF RELATED ART

Electronic apparatuses, which provide a user with an image, such as, for example, smartphones, digital cameras, notebook computers, navigation systems, and smart televisions, include a display device for displaying an image. The display device generates an image, and provides the image to a user through a display screen. The display device may be provided in a state in which an upper substrate and a lower substrate are attached to each other by a sealing part. The sealing part is usually disposed at a peripheral area of the display device and enclosing a filling member. During the curing of the sealing part and the filling member, if the sealing part is not sufficiently cured to be able to enclose the floating filling member, defective bonding of the upper substrate and the lower substrate by the sealing part may occur.

### SUMMARY

The present inventive concept provides a display device in which a bonding force between substrates is enhanced, and therefore provides a display device with enhanced durability.

An embodiment of the present inventive concept provides a display device including a first substrate including an active region and a peripheral region adjacent to the active region, a circuit element layer disposed on the first substrate and including a plurality of insulating layers and at least one transistor, a display element layer disposed on the circuit element layer and including a pixel-defining layer having an opening defined therein, and overlapping the active region, a light-emitting element including a first electrode at least partially exposed by the opening, a second electrode, and a light-emitting layer disposed between the first and second electrodes, and a partition wall overlapping the peripheral region, a second substrate disposed on the display element layer, a sealing member disposed between the circuit element layer and the second substrate to define an inner space, and overlapping the peripheral region, and a filling member disposed in the inner space, in which a recessed portion overlapping the peripheral region is defined in a rear surface of the second substrate facing the display element layer, and a part of the filling member is disposed in the recessed portion.

In an embodiment of the present inventive concept, on a plane, the recessed portion, the partition wall, and the sealing member may be adjacent to the active region in this order.

In an embodiment of the present inventive concept, the second electrode may overlap the active region and the peripheral region, and cover the partition wall.

In an embodiment of the present inventive concept, the display device may further include an upper organic layer disposed on the second electrode, and overlapping the active region and the peripheral region, in which the upper organic layer may be in contact with the filling member.

In an embodiment of the present inventive concept, a part of the upper organic layer overlapping the partition wall may be in contact with the rear surface of the second substrate.

In an embodiment of the present inventive concept, the recessed portion may be provided in plurality, and the recessed portions may be arranged spaced apart from each other in a direction far away from the active region.

In an embodiment of the present inventive concept, the recessed portion may be defined by a first inner surface parallel to the rear surface and a second inner surface connecting the first inner surface and the rear surface, and an angle between the first inner surface and the second inner surface may be at least a right angle.

In an embodiment of the present inventive concept, the partition wall may be provided in plurality, and the partition walls may be arranged spaced apart from each other in a direction far away from the active region.

In an embodiment of the present inventive concept, in an insulating layer contacting the partition wall and the second electrode among the insulating layers, a pattern portion, which is obtained by partially removing the insulating layer contacting the partition wall and the second electrode from a front surface facing the second substrate, and overlaps the recessed portion, may be defined.

In an embodiment of the present inventive concept, the display device may further include a sub partition wall disposed between the pixel-defining layer and the partition wall, and overlapping the peripheral region, in which a valley region between the partition wall and the sub partition wall may overlap the recessed portion.

In an embodiment of the present inventive concept, the recessed portion may have, on a plane, a closed line shape surrounding the active region.

In an embodiment of the present inventive concept, on a plane, the recessed portion may include short-side patterns extending in a first direction, and spaced apart from each other in a second direction crossing the first direction with the active region therebetween, and long-side patterns extending in the second direction, and spaced apart from each other in the first direction with the active region therebetween, and the short-side patterns and the long-side patterns may be spaced apart from each other at corners of the active region.

In an embodiment of the present inventive concept, the recessed portion may include a plurality of patterns, and the patterns may be arranged spaced apart from each other while surrounding the active region.

In an embodiment of the present inventive concept, the recessed portion may have a thickness of about 5 μm to about 20 μm.

In an embodiment of the present inventive concept, the partition wall may have a thickness of about 3 μm to about 5 μm, a width of the partition wall in one direction may be about 10 μm to about 50 μm, and a width of the recessed portion in the one direction may be greater than the width of the partition wall.

In an embodiment of the present inventive concept, the sealing member may include any one among silicone, epoxy, and an acryl-based thermosetting material, and have a viscosity of about 3000 cps to about 40000 cps.

In an embodiment of the present inventive concept, the display device may further include a floating pattern disposed on a layer the same as that of one of electrodes included in the transistor and overlapping the peripheral region, in which the floating pattern may be in contact with the sealing member.

In an embodiment of the present inventive concept, a display device includes a first substrate including an active region and a peripheral region adjacent to the active region, a plurality of insulating layers disposed on the first substrate, a pixel-defining layer having an opening defined therein, and overlapping the active region, a partition wall disposed on a layer the same as that of the pixel-defining layer, and overlapping the peripheral region, a light-emitting element disposed on the first substrate and including a first electrode at least partially exposed by the opening, a second electrode, and a light-emitting layer disposed between the first and second electrodes, a second substrate disposed on the light-emitting element and having therein a recessed portion overlapping the peripheral region, a sealing member overlapping the peripheral region, and disposed between one of the insulating layers and the second substrate to define an inner space, and a filling member disposed in the inner space, in which on a plane, the recessed portion, the partition wall, and the sealing member are adjacent to the active region in this order.

In an embodiment of the present inventive concept, the recessed portion may have, on a plane, a closed line shape surrounding the active region.

In an embodiment of the present inventive concept, the recessed portion may have, on a cross-section, a trapezoidal shape.

### BRIEF DESCRIPTION OF THE DRAWINGS

The accompanying drawings are included to provide a further understanding of the present inventive concept. The drawings illustrate embodiments of the present inventive concept and, together with the description, serve to explain principles of the present inventive concept. In the drawings:

FIG. 1A is a combined perspective view of a display device according to an embodiment of the present inventive concept;

FIG. 1B is an exploded perspective view of a display device according to an embodiment of the present inventive concept;

FIG. 2 is a cross-sectional view of a display device according to an embodiment of the present inventive concept;

FIG. 3 is a cross-sectional view of an active region of a display panel according to an embodiment of the present inventive concept;

FIG. 4 is a plan view of a display panel according to an embodiment of the present inventive concept;

FIG. 5 is a plan view of a sensing panel according to an embodiment of the present inventive concept;

FIG. 6 is a cross-sectional view taken along I-I′ of FIG. 1B;

FIG. 7 is a plan view illustrating an arrangement relationship of a recessed portion, a partition wall, and a sealing member according to an embodiment of the present inventive concept;

FIG. 8 is a cross-sectional view of a display panel according to an embodiment of the present inventive concept;

FIG. 9 is a cross-sectional view of a display panel according to an embodiment of the present inventive concept;

FIG. 10 is a cross-sectional view of a display panel according to an embodiment of the present inventive concept;

FIG. 11 is a cross-sectional view of a display panel according to an embodiment of the present inventive concept;

FIG. 12 is a cross-sectional view of a display panel according to an embodiment of the present inventive concept;

FIG. 13 is a plan view illustrating an arrangement relationship of a recessed portion, a partition wall, and a sealing member according to an embodiment of the present inventive concept; and

FIG. 14 is a plan view illustrating an arrangement relationship of a recessed portion, a partition wall, and a sealing member according to an embodiment of the present inventive concept.

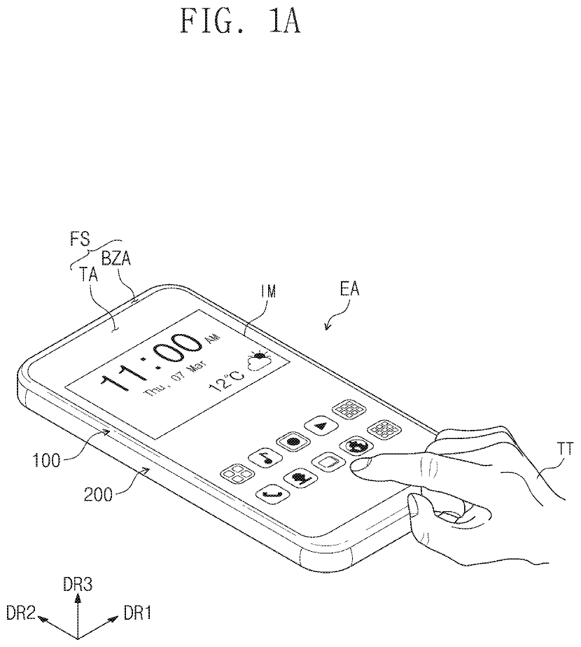

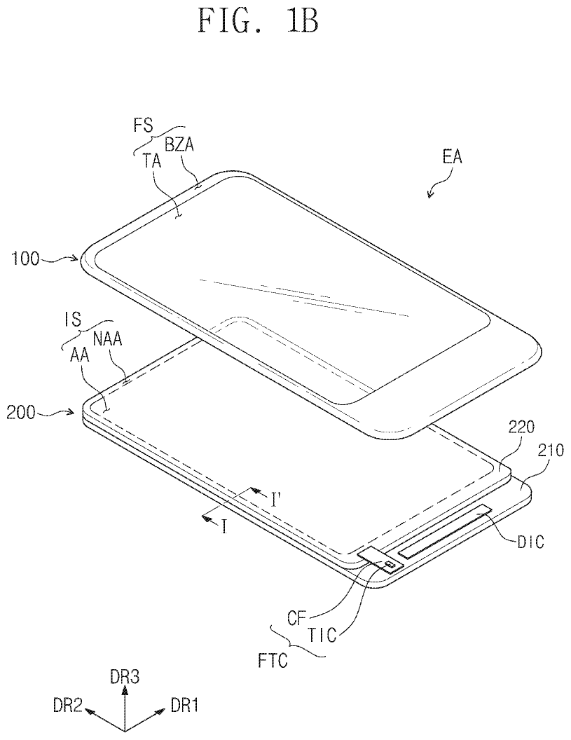

Since the drawings in FIGS. 1-14 are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

In this specification, when a component (or region, layer, portion, etc.) is referred to as “on”, “connected”, or “coupled” to another component, it means that it is placed/connected/coupled directly on or to the other component or a third component can be disposed between them.

Like reference numerals or symbols refer to like elements. “And/or” includes any and all combinations that the associated elements may define.

Terms such as “first”, “second”, etc. may be used to describe various components, but the components should not be limited by the terms. These terms are only used for the purpose of distinguishing one component from other components. For example, without departing from the scope and spirit of the present inventive concept, a first component may be referred to as a second component, and similarly, a second component may be referred to as a first component. Singular expressions are intended to include plural expressions unless the context clearly indicates otherwise.

In addition, terms such as “below”, “lower”, “above”, and “upper” are used to describe the relationship between components shown in the drawings. The terms are relative concepts and are described based on the directions indicated in the drawings, and it will be understood that these spatially relative terms are intended to encompass different orientations of the device in use or operation, in addition to the orientation illustrated in the drawings.

Terms such as “include” or “have” are intended to designate the presence of a feature, number, step, operation, component, part, or combinations thereof described in the specification, and it should be understood that it does not preclude the presence or addition of one or more other features, numbers, steps, operations, components, parts, or combinations thereof.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms (including technical and scientific terms) used in this specification have the same meaning as commonly understood by one of ordinary skill in the art to which the present inventive concept belongs. In addition, terms such as terms defined in commonly used dictionaries should be interpreted as having a meaning consistent with the meaning in the context of the related technology, and should not be interpreted in an ideal or overly formal sense unless explicitly defined here.

Hereinafter, embodiments of the present inventive concept will be described with reference to the drawings.

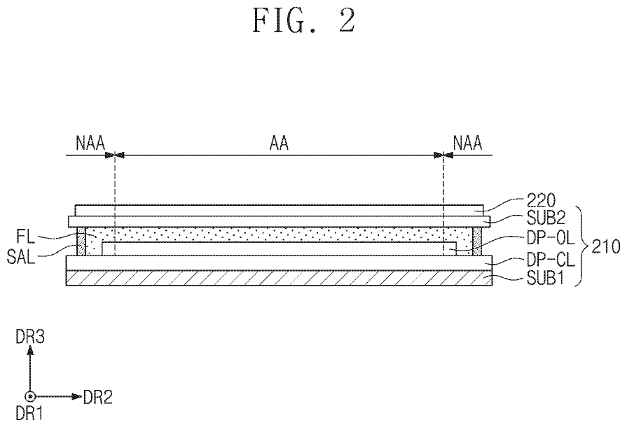

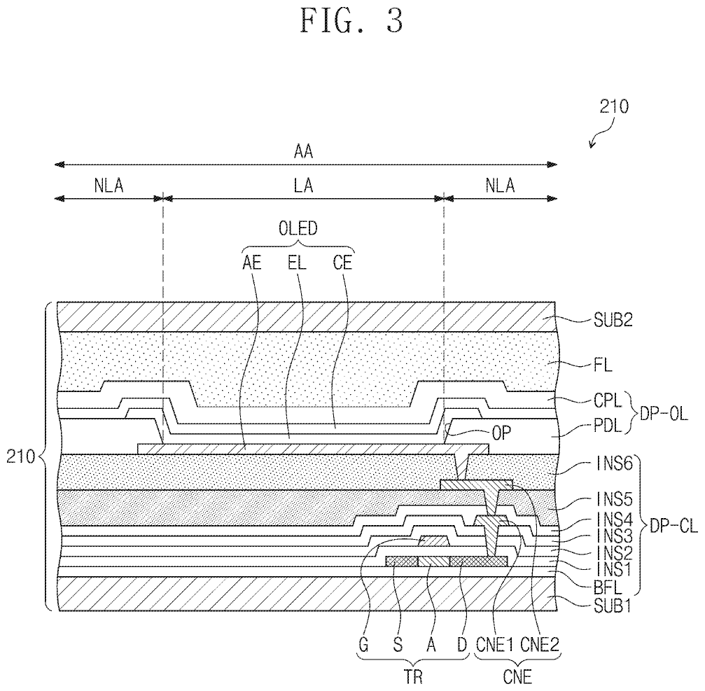

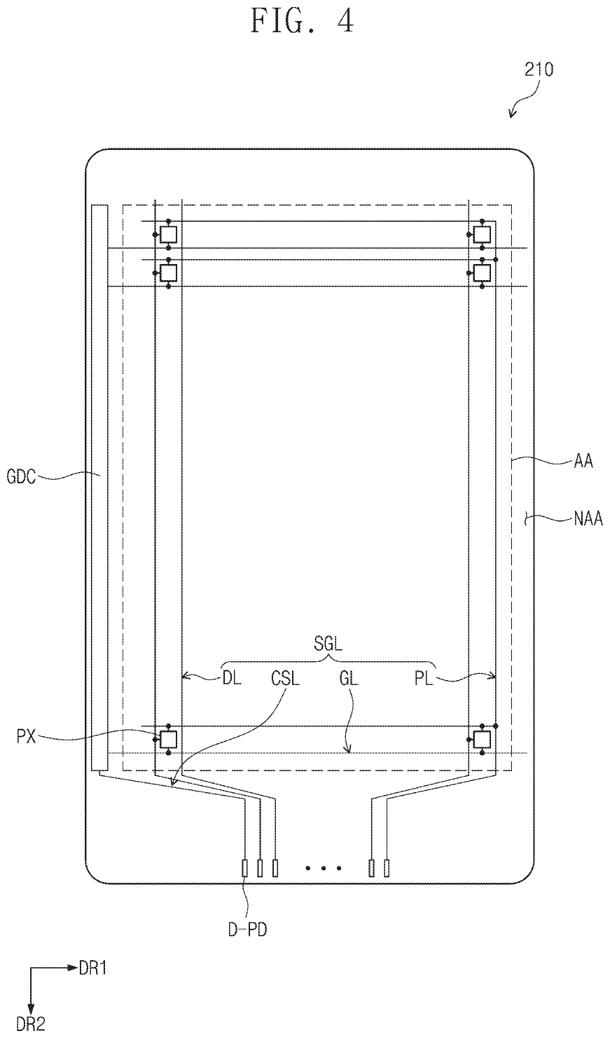

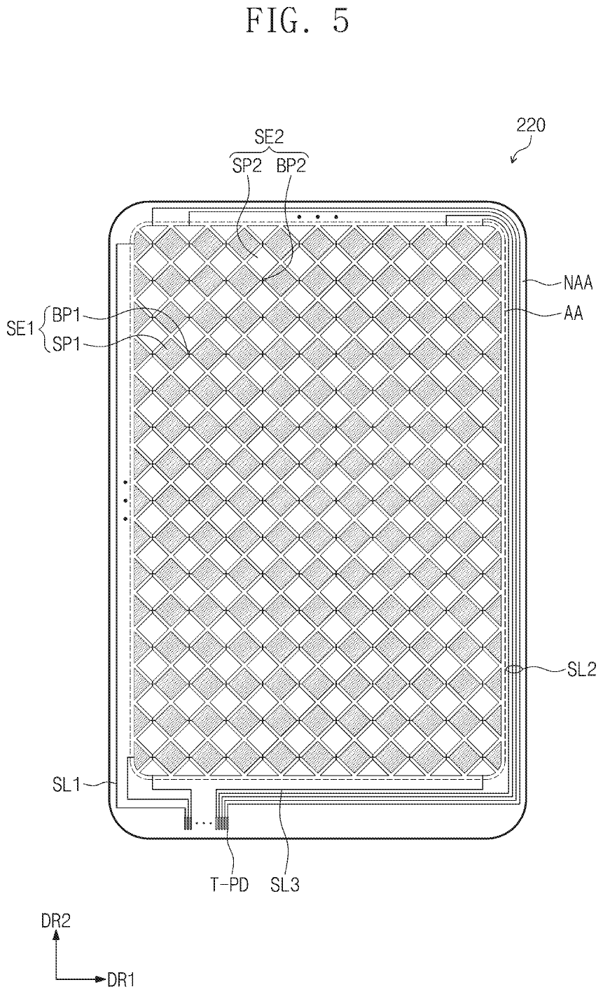

FIG. 1A is a combined perspective view of a display device according to an embodiment of the present inventive concept. FIG. 1B is an exploded perspective view of a display device according to an embodiment of the present inventive concept. FIG. 2 is a cross-sectional view of a display device according to an embodiment of the present inventive concept. FIG. 3 is a cross-sectional view of an active region of a display panel according to an embodiment of the present inventive concept. FIG. 4 is a plan view of a display panel according to an embodiment of the present inventive concept. FIG. 5 is a plan view of a sensing panel according to an embodiment of the present inventive concept.

Referring to FIGS. 1A and 1B, a display device EA may be a device activated in response to an electrical signal. The display device EA may include various embodiments. For example, the display device EA may include, for example, a tablet computer, a notebook computer, a computer, a smart television, a vehicle navigation system, a game console, a billboard, or the like. In the present embodiment, a smartphone is exemplarily illustrated as the display device EA.

The display device EA may display an image IM through a display surface FS. The image IM may include at least one of a static image or a dynamic image. The display surface FS is parallel to a surface defined by a first direction DR1 and a second direction DR2. The normal direction of the display surface FS, that is, a thickness direction of the display device EA indicates a third direction DR3. The front surface (or upper surface) and the rear surface (or lower surface) of each member or unit to be described hereinafter are distinguished by the third direction DR3.

The display surface FS on which the image IM is displayed may correspond to the front surface of the display device EA, and the display surface FS of the display device EA may substantially correspond to the front surface of a window member 100. The display surface FS may be a flat surface. However, the present inventive concept is not limited thereto. For example, the display surface FS may be a curved surface or a three-dimensional surface. The three-dimensional display surface, in which images are generated within a display volume rather than upon a stationary surface, may include a plurality of display areas, for example, a polyprism surface. The plurality of display areas may be oriented in different directions. Hereinafter, a display surface, the front surface of the display device EA, and the front surface FS of the window member 100 are denoted as the same reference numeral or symbol. FIG. 1A illustrates a clock and a plurality of icons as an example of the image IM.

The display device EA includes the window member 100 and an electronic panel 200. The display device EA may further include an optical member disposed between the window member 100 and the electronic panel 200. The optical member may include a polarizer and/or a retarder. The optical member may include a color filter member that reduces the reflectivity of external light. The color filter member may include different color filters each selectively transmitting lights within a specified wavelength range and blocking lights outside that wavelength range.

The window member 100 may be formed of a transparent material capable of outputting the image IM. The window member 100 includes a base panel. For example, the base panel may be composed of, for example, glass, plastic, or a combination thereof. The front surface FS of the window member 100 includes a transmission region TA and a bezel region BZA. The transmission region TA may be a region in which the image IM is displayed. The transmission region TA may be an optically transparent region. For example, the transmission region TA may be a region having a visible light transmittance of about 90% or more.

The bezel region BZA may be a region having a relatively lower light transmittance than the transmission region TA, and may include an opaque material that blocks a light. The bezel region BZA defines the shape of the transmission region TA. The bezel region BZA may be adjacent to the transmission region TA, and may surround the transmission region TA. However, this is illustratively shown, and the bezel region BZA may be disposed adjacent to only one side of the transmission region TA, or may be omitted. The window member 100 may further include a colored light-blocking pattern disposed in the base panel to define the bezel region BZA. For example, when the window member 100 is provided as a glass or plastic substrate, the bezel region BZA may be a color layer printed or deposited on one side of a glass or plastic substrate. For example, the bezel region BZA may be formed by coloring the corresponding area of the glass or plastic substrate.

The bezel region BZA may have a predetermined color. The bezel region BZA may cover a peripheral region NAA of the electronic panel 200 to block the peripheral region NAA from being viewed from the outside. Meanwhile, this is exemplarily illustrated, and in the window member 100 according to an embodiment of the present inventive concept, the bezel region BZA may be omitted.

The electronic panel 200 may display the image IM, and sense an external input TT. The image IM may be displayed on the front surface IS of the electronic panel 200. The front surface IS of the electronic panel 200 includes an active region AA and the peripheral region NAA. The active region AA may be a region activated in response to an electrical signal.

In the present embodiment, the active region AA may be a region on which the image IM is displayed, and in which the external input TT is simultaneously sensed. The active region AA corresponds to the transmission region TA, and the peripheral region NAA corresponds to the bezel region BZA. In this specification, the wording “a region/part corresponds to a region/part” means “overlapping each other”, and is not limited as having the same area and/or shape. For example, the transmission region TA overlaps the entire surface or at least part of the active region AA. The image IM displayed on the active region AA of the electronic panel 200 may be viewed from the outside through the transmission region TA.

The electronic panel 200 includes a display panel 210, a sensing panel 220, a driving circuit DIC, and a circuit module FTC.

The display panel 210 substantially generates the image IM. The display panel 210 may be an organic light-emitting display panel or a quantum dot light-emitting display panel. The panels are distinguished depending on constituent materials of light-emitting elements. A light-emitting layer of the organic light-emitting display panel may include an organic light-emitting material. A light-emitting layer of the quantum dot light-emitting display panel may include quantum dots, quantum rods, and/or the like. Alternatively, the display panel 210 may be, for example, an inorganic light-emitting display panel, which may include an inorganic light-emitting material. The inorganic light-emitting material may include crystalline semiconductors such as, for example, gallium nitride (GaN), indium phosphide (InP), etc. Hereinafter, the organic light-emitting display panel will be described as the display panel 210.

The sensing panel 220 senses an external input (for example, a touch event) applied from the outside. In the present embodiment, the sensing panel 220 may be a capacitive panel. For example, the sensing panel 220 may obtain coordinate information by using a mutual-capacitive sensing method and/or a self-capacitive sensing method. However, the present inventive concept is not limited thereto.

The driving circuit DIC is disposed on the display panel 210, and may be mounted on the display panel 210. The display panel 210 may not be bent. However, the present inventive concept is not limited thereto. In an embodiment of the present inventive concept, a portion of the display panel 210, on which the driving circuit DIC is mounted, may be bent such that the driving circuit DIC is disposed on a rear surface of the electronic panel 200. The driving circuit DIC is electrically connected to the display panel 210 to provide the display panel 210 with an electrical signal for driving the display panel 210.

The circuit module FTC is electrically connected to the sensing panel 220. In the present embodiment, the circuit module FTC may include a flexible circuit board CF and a sensing driving circuit TIC. The flexible circuit board CF includes lines. The lines electrically connect the sensing panel 220 and the sensing driving circuit TIC. The sensing driving circuit TIC may be mounted and provided on the flexible circuit board CF in a form of a chip-on-film. An example in which the display device EA according to an embodiment of the present inventive concept includes one flexible circuit board CF is illustrated, but the present inventive concept is not limited thereto. For example, in an embodiment of the present inventive concept, the display device EA may include a plurality of flexible circuit boards capable of being connected with the display panel 210.

The circuit module FTC may connect the display panel 210 and the sensing panel 220. The sensing driving circuit TIC may be omitted. The sensing driving circuit TIC and the driving circuit DIC may be integrated.

Referring to FIG. 2, the display panel 210 may include a first substrate SUB1, a circuit element layer DP-CL, a display element layer DP-OL, a second substrate SUB2, a sealing member SAL, and a filling member FL. The sensing panel 220 may be disposed on the second substrate SUB2.

The first substrate SUB1 may include an active region AA and a peripheral region NAA adjacent to the active region AA. The display element layer DP-OL may overlap the active region AA. In the present embodiment, the first substrate SUB1 may be a rigid type. For example, the first substrate SUB1 may include, for example, a glass substrate, a metal substrate, a polymer substrate, or an organic/inorganic composite material substrate. Alternatively, the first substrate SUB1 may be a flexible type, and may include, for example, polyimide (PI), and thus, at least a part of the electronic panel 200 may be easily bent.

The circuit element layer DP-CL is disposed on the first substrate SUB1. The circuit element layer DP-CL includes at least one insulating layer and a circuit element. The insulating layer includes at least one inorganic film and at least one organic film. The circuit element includes a signal line, a driving circuit of a pixel, etc. The driving circuit of the pixel may include at least one transistor. The circuit element layer DP-CL may be formed through a process of forming an insulating layer, a semiconductor layer, and a conductive layer by coating, deposition, or the like, and a process of patterning the insulating layer, the semiconductor layer, and the conductive layer through photolithography.

Referring to FIG. 3, a pixel according to an embodiment of the present inventive concept may be defined as including a transistor TR and a light-emitting element OLED. The light-emitting element OLED may include a first electrode AE (or anode), a second electrode CE (or cathode), and a light-emitting layer EL. The light-emitting element OLED according to an embodiment of the present inventive concept may further include a hole control layer disposed between the first electrode AE and the light-emitting layer EL, and an electron control layer between the light-emitting layer EL and the second electrode CE. The hole control layer may include a hole transport layer and may further include a hole injection layer. The electron control layer may include an electron transport layer and may further include an electron injection layer.

The transistor TR and the light-emitting element OLED may be disposed on the first substrate SUB1. One transistor TR is exemplarily illustrated, but a pixel PX may substantially include a plurality of transistors and at least one capacitor for driving the light-emitting element OLED.

The active region AA may include a light-emitting region LA corresponding to each of pixels and a non-light-emitting region NLA around the light-emitting region LA. For example, the non-light-emitting region NLA may surround the light-emitting region LA.

A buffer layer BFL may be disposed on the first substrate SUB1, and the buffer layer BFL may be an inorganic layer. A semiconductor pattern may be disposed on the buffer layer BFL. The buffer layer BFL may be configured to reduce or block penetration of foreign materials, moisture, or ambient air from a bottom portion of the first substrate SUB1 and may provide a flat surface on the first substrate SUB1. The semiconductor pattern may include, for example, polysilicon (p-Si), amorphous silicon (a-Si), or a metal oxide. The metal oxide may include an oxide of at least one material selected from, for example, indium (In), gallium (Ga), stannum (Sn), zirconium (Zr), vanadium (V), hafnium (Hf), cadmium (Cd), germanium (Ge), chromium (Cr), titanium (Ti), and zinc (Zn).

The semiconductor pattern may be doped with an N-type dopant or a P-type dopant. The N-type dopants may include, for example, phosphorus (P), arsenic (As), etc. The P-type dopants may include, for example, boron (B), aluminum (Al), gallium (Ga), etc. The semiconductor pattern may include a heavily doped region and a lightly doped region. The heavily doped region may have a higher conductivity than the lightly doped region, and substantially serve as a source electrode and a drain electrode of the transistor TR. The lightly doped region may substantially correspond to an active (or channel) of the transistor. The active (or channel) may be an undoped region.

A source S, an active A (i.e., a channel), and a drain D of the transistor TR may be formed from the semiconductor pattern. The source S and the drain D may extend from the active A (i.e., the channel) in directions facing away from each other in a cross-sectional view, and may be arranged respectively on opposite sides of the active A (i.e., the channel). A first insulating layer INS1 may be disposed on the semiconductor pattern and the buffer layer BFL. A gate G of the transistor TR may be disposed on the first insulating layer INS1, and may overlap the active A (i.e., the channel). A second insulating layer INS2 may be disposed on the first insulating layer INS1, and may cover the gate G. A third insulating layer INS3 may be disposed on the second insulating layer INS2.

A connection electrode CNE may include a first connection electrode CN1 and a second connection electrode CNE2 for connecting the transistor TR and the light-emitting element OLED. However, either of the first connection electrode CNE1 and the second connection electrode CNE2 may be omitted. The first connection electrode CNE1 may be disposed on the third insulating layer INS3, and may be connected to the drain D through a first contact hole defined in first to third insulating layers INS1 to INS3.

A fourth insulating layer INS4 may be disposed on the third insulating layer INS3, and may cover the first connection electrode CNE1. A fifth insulating layer INS5 may be disposed on the fourth insulating layer INS4. The fifth insulating layer INS5 may be an organic layer, and may have a flat top surface. The second connection electrode CNE2 may be disposed on the fifth insulating layer INS5. The second connection electrode CNE2 may be connected to the first connection electrode CNE1 through a second contact hole defined in fourth and fifth insulating layers INS4 and INS5.

A sixth insulating layer INS6 may be disposed on the fifth insulating layer INS5, and may cover the second connection electrode CNE2. The sixth insulating layer INS6 may be an organic layer, and may have a flat top surface. Layers from the buffer layer BFL to the sixth insulating layer INS6 may be defined as the circuit element layer DP-CL. First to sixth insulating layers INS1 to INS6 may be inorganic layers or organic layers. In an embodiment of the present inventive concept, the first to fourth insulating layers INS1 to INS4 may be inorganic layers, and the fifth and sixth insulating layers INS5 and INS6 may be organic layers.

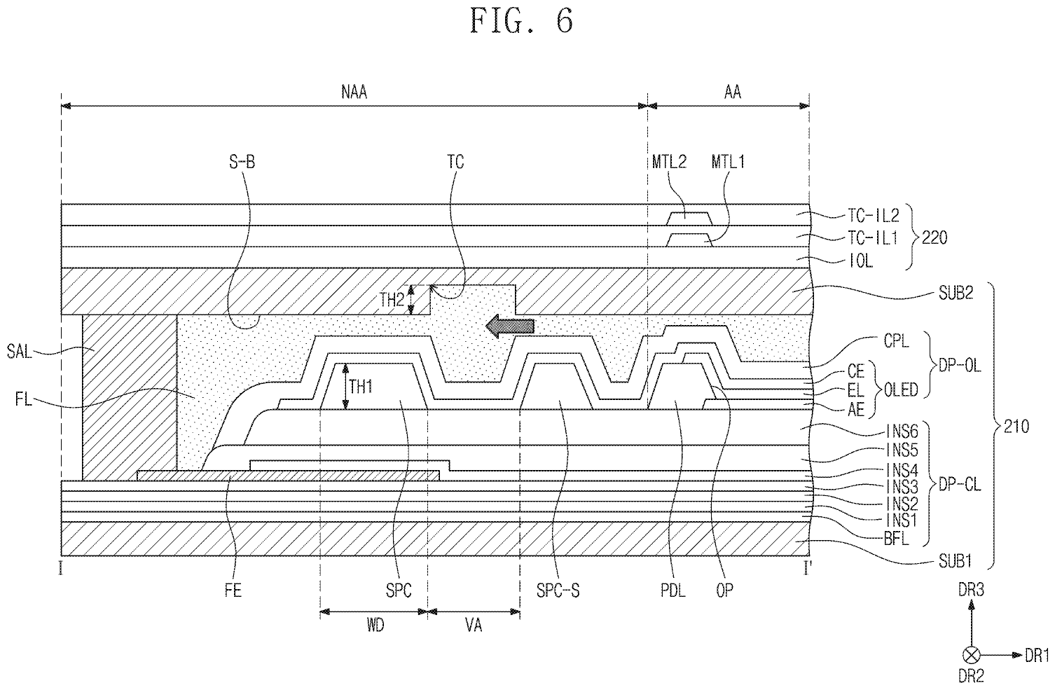

The display element layer DP-OL may include a light-emitting element OLED, a pixel-defining layer PDL, and a partition wall SPC (see FIG. 6) which is described later.

The light-emitting element OLED may include the first electrode AE, the second electrode CE, and the light-emitting layer EL. The first electrode AE may also be referred to as a pixel electrode or an anode electrode, and the second electrode CE may also be referred to as a common electrode or a cathode electrode. The first electrode AE may be disposed on the sixth insulating layer INS6. The first electrode AE may be connected to the second connection electrode CNE2 through a third contact hole defined in the sixth insulating layer INS6. The pixel-defining layer PDL, in which an opening OP for exposing a predetermined part of the first electrode AE is defined, may be disposed on the sixth insulating layer INS6 and may cover a portion of the first electrode AE. In an embodiment of the present inventive concept, the pixel-defining layer PDL may include an organic material such as, for example, polyimide, but the present inventive concept is not limited thereto. In the present embodiment, the light-emitting region LA may correspond to the area of the first electrode AE exposed by the opening OP, and the non-light-emitting region NLA may correspond to a region overlapping the pixel-defining layer PDL.

The light-emitting layer EL may be disposed on the first electrode AE and on a region corresponding to the opening OP. For example, the light-emitting layer EL may be independently disposed for each pixel. The light-emitting layer EL may include an organic material and/or an inorganic material. The light-emitting layer EL may generate one light among red light, green light, and blue light. However, the present inventive concept is not limited thereto. For example, the light-emitting layer EL may be provided to be connected in common with the pixels. In this case, the light-emitting layer EL may provide a blue light or may provide a white light.

The second electrode CE may be disposed on the light-emitting layer EL. The second electrode CE may be disposed in pixels in common. Accordingly, the second electrode CE may be entirely disposed on the light-emitting region LA and the non-light-emitting region NLA. In an embodiment of the present inventive concept, the second electrode CE may include a transparent conductive material or a semi-transparent conductive material. Accordingly, light generated in the light-emitting layer EL may be easily emitted toward the third direction DR3 through the second electrode CE. In the present embodiment, a layer on which the light-emitting element OLED is disposed may be defined as the display element layer DP-OL.

The light emitting layer EL may emit light in response to a potential difference between the first electrode AE and the second electrode CE. A first voltage may be applied to the first electrode AE through the transistor TR, and a second voltage may be applied to the second electrode CE. Holes and electrons injected to the light-emitting layer EL may be combined to form excitons, and the light-emitting element OLED may emit light when the excitons transition to a ground state.

The display element layer DP-OL according to an embodiment of the present inventive concept may further include an upper organic layer CPL. The upper organic layer CPL may cover the second electrode CE, and be entirely disposed on the light-emitting region LA and the non-light-emitting region NLA. The upper organic layer CPL may include an organic material, and have a greater thickness than the second electrode CE.

A filling member FL may be disposed on the display element layer DP-OL to cover a pixel. The filling member FL may be in contact with the upper organic layer CPL and the rear surface of the second substrate SUB2. For example, the upper organic layer CPL may be disposed on the second electrode CE, overlapping the active region AA and the peripheral region NAA, and contacting the filling member FL. In the present inventive concept, “the rear surface of the second substrate SUB2” may be defined as the surface facing the display element layer DP-OL within two horizontal surfaces of the second substrate SUB2. The second substrate SUB2 may be disposed on the filling member FL.

The second substrate SUB2 is disposed opposite to the first substrate SUB1 to cover the display element layer DP-OL. The second substrate SUB2 according to an embodiment of the present inventive concept may be an encapsulation substrate. The second substrate SUB2 may include, for example, a glass substrate, a metal substrate, a polymer substrate, or an organic/inorganic composite material substrate.

Referring to FIG. 2 again, a sealing member SAL is disposed between the first substrate SUB1 and the second substrate SUB2. The sealing member SAL may be disposed on the circuit element layer DP-CL, and overlap the peripheral region NAA. The sealing member SAL may have, on a plane, a closed loop shape surrounding the active region AA. The first substrate SUB1 and the second substrate SUB2 may be attached to each other using the sealing member SAL. The sealing member SAL may include a thermosetting material or a light curing material. However, a material of the sealing member SAL is not limited thereto. For example, in an embodiment of the present inventive concept, the sealing member SAL may include an inorganic material, for example, frit, and the frit may include a crystalized (fully and/or partially crystallized) base or mother glass.

The filling member FL may fill an inner space defined by the first substrate SUB1, the second substrate SUB2, and the sealing member SAL. For example, the first substrate SUB1 and the second substrate SUB2 may be assembled together by the sealing member SAL located on the peripheral region NAA surrounding the active region AA, and also by the filling member FL filling a space inside the sealing member SAL. For example, the filling member FL may fill the space surrounded by the sealing member SAL.

The filling member FL may include, for example, silicone, epoxy, or an acryl-based thermosetting material. In the present embodiment, the filling member FL may have a viscosity of about 3000 cps to about 40000 cps.

After the circuit element layer DP-CL and the display element layer DP-OL are formed on the first substrate SUB1, a process for attaching the sealing member SAL and the filling member FL, which are adhered to the second substrate SUB2, to the first substrate SUB1 is performed. At this time, the sealing member SAL may be cured by irradiating the sealing member SAL with a laser beam. During curing of the sealing member SAL, the filling member FL may fill the inner space while moving from the active region AA toward the peripheral region NAA between the display element layer DP-OL and the second substrate SUB2. When the filling member FL comes into contact with the sealing member SAL before the sealing member SAL is cured, the sealing member SAL may be peeled off. Accordingly, a bonding force between the display element layer DP-OL and the second substrate SUB2 may decrease.

Referring to FIG. 4, the display panel 210 may include a driving circuit GDC, a plurality of signal lines SGL, and a plurality of pixels PX.

The driving circuit GDC may be disposed in the peripheral region NAA, and may include a scanning driving circuit. The scanning driving circuit generates a plurality of scanning signals, and sequentially outputs the scanning signals to a plurality of scanning lines GL to be described later. The scanning signals may be applied to the pixels PX through the scanning lines GL. The scanning driving circuit may further output another control signal to driving circuits of the pixels PX.

The scanning driving circuit may include a plurality of transistors formed through a process the same as a process for manufacturing the driving circuits of the pixels PX, such as a low temperature polycrystalline silicon (LTPS) process, or a low temperature polycrystalline oxide (LTPO) process.

The signal lines SGL includes scanning lines GL, data lines DL, a power line PL, and a control signal line CSL. The scanning lines GL are respectively connected to corresponding pixels PX of the pixels PX, and the data lines DL are respectively connected to corresponding pixels PX of the pixels PX. The power line PL is connected to the pixels PX. The control signal line CSL may provide the scanning circuit with control signals.

The data lines DL, the power line PL, and the control signal line CSL may be connected to a corresponding pad of display pads D-PD disposed in the peripheral region NAA. The display pads D-PD may be adjacent to the lower end of the display panel 210. The display pads D-PD may be connected to the driving circuit DIC (see FIG. 1B).

Referring to FIG. 5, a sensing panel 220 is disposed on the second substrate SUB2. The sensing panel 220 may include a plurality of sensing electrodes SE1 and SE2, and a plurality of signal lines SL1, SL2, and SL3 connected to the plurality of sensing electrodes SE1 and SE2.

The sensing electrodes SE1 and SE2 are disposed in the active region AA. The sensing electrodes SE1 and SE2 may include a plurality of first sensing electrodes SE1 and a plurality of second sensing electrodes SE2 crossing each other. The first sensing electrodes SE1 may each extend along the first direction DR1, and be arranged along the second direction DR2. The first sensing electrodes SE1 may include a plurality of first sensing parts SP1 and a plurality of intermediate parts BP1 arranged along the first direction DR1. At least one intermediate part BP1 may be disposed between two adjacent first sensing parts SP1. Two first sensing parts SP1 disposed at opposite ends of one row of the first sensing electrodes SE1 may each be smaller in size than each of first sensing parts SP1 disposed at the center, for example, may each have a size corresponding to half a size of each of the first sensing parts SP1 disposed at the center.

The second sensing electrodes SE2 may each extend along the second direction DR2, and be arranged along the first direction DR1. The second sensing electrodes SE2 may include a plurality of second sensing parts SP2 and a plurality of bridges BP2 arranged along the second direction DR2. Two second sensing parts SP2 disposed at opposite ends of one column of the second sensing electrodes SE2 may each be smaller in size than each of second sensing parts SP2 disposed at the center, for example, may each have a size corresponding to half a size of each of the second sensing parts SP2 disposed at the center. The bridges BP2 and the second sensing parts SP2 may be disposed on layers different from each other.

The signal lines SL1, SL2, and SL3 are disposed in the peripheral region NAA. The signal lines SL1, SL2, and SL3 include a plurality of first signal lines SL1, a plurality of second signal lines SL2, and a plurality of third signal lines SL3.

The first signal lines SL1 are each connected to one end of both ends of each of the first sensing electrodes SE1. The second signal lines SL2 are each connected to one end of both ends of each of the second sensing electrodes SE2. The third signal lines SL3 are each connected to the other end of both ends of each of the second sensing electrodes SE2. Since the second sensing electrodes SE2 are longer than the first sensing electrodes SE1, a voltage drop of a detection signal (or a transmission signal) occurs, and thus, sensing sensitivity may be reduced. Thus, the second signal lines SL2 and the third signal lines SL3 are connected to two opposite ends of the second sensing electrodes SE2, a voltage drop of a detection signal (or a transmission signal) may be prevented and thus reduction of sensing sensitivity may be prevented. However, the connection relationship of the sensing electrodes SE1 and SE2 and the signal lines SL1, SL2, and SL3 is not limited thereto.

The signal lines SL1, SL2, and SL3 may be respectively connected to corresponding pads of the sensing pads T-PD disposed on the peripheral region NAA. A circuit module FTC (see FIG. 1B) may be connected to the sensing pads T-PD.

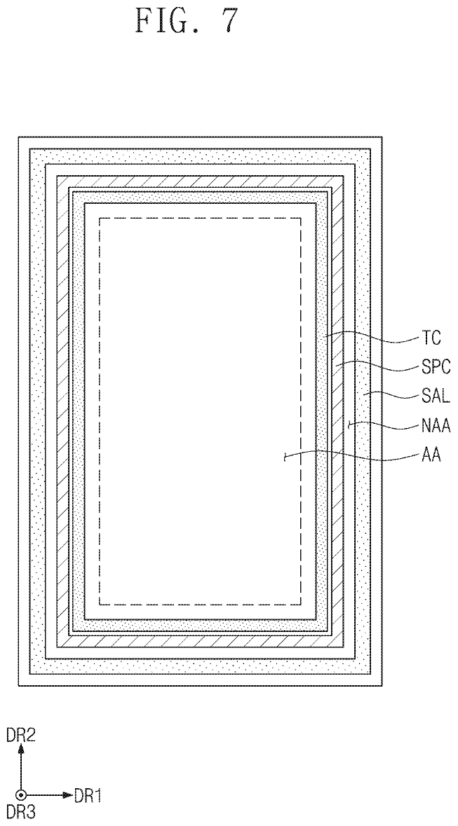

FIG. 6 is a cross-sectional view taken along I-I′ of FIG. 1B. FIG. 7 is a plan view illustrating an arrangement relationship of a recessed portion, a partition wall, a sealing member according to an embodiment of the present inventive concept.

A circuit element layer DP-CL of a display panel 210 according to the present embodiment may further include a floating pattern FE. The floating pattern FE may be disposed on a third insulating layer INS3, and overlap a peripheral region NAA. One part of the floating pattern FE may be in contact with the sealing member SAL.

The floating pattern FE may be disposed on a layer the same as that of one of electrodes of a transistor TR (see FIG. 3). For example, both the floating pattern FE and the first connection electrode CNE1 may be disposed on the third insulating layer INS3. The floating pattern FE may include metal or alloy. FIG. 6 exemplarily illustrates the floating pattern FE disposed on the third insulating layer INS3, but the position of the floating pattern FE is not limited thereto. The floating pattern FE may be in a state of being floated with respect to the transistor TR (see FIG. 3).

Metals are better conductors of heat than most other materials. Since the floating pattern FE includes metal or alloy and is in contact with the sealing member, the transfer efficiency of heat applied to the sealing member SAL may be increased while the sealing member SAL is being cured through irradiation with laser beams. Accordingly, a curing speed of the sealing member SAL may be enhanced.

A display element layer DP-OL according to an embodiment of the present inventive concept may include a partition wall SPC and a sub partition wall SPC-S. The partition wall SPC and the sub partition wall SPC-S may be disposed on a sixth insulating layer INS6 and disposed on a layer the same as that of a pixel-defining layer PDL, and may include a material the same as that of the pixel-defining layer PDL. Accordingly, the partition wall SPC and the sub partition wall SPC-S may include an organic material. The partition wall SPC, the sub partition wall SPC-S, and the pixel-defining layer PDL may be structures patterned in the same process.

According to the present embodiment, the pixel-defining layer PDL may be disposed in an active region AA, and the partition wall SPC and the sub partition wall SPC-S may be disposed in the peripheral region NAA. The sub partition wall SPC-S may be disposed relatively more adjacent to the active region AA than the partition wall SPC. For example, the sub partition wall SPC-S may be disposed between the partition wall SPC and the active region AA. A region between the partition wall SPC and the sub partition wall SPC-S may be defined as a valley region VA. The sub partition wall SPC-S may be spaced apart from the partition wall SPC in the peripheral region NAA, with the sub partition wall SPC-S and the partition wall SPC each surrounding the active region AA.

The second electrode CE may overlap the active region AA and the peripheral region NAA. The partition wall SPC, the sub partition wall SPC-S, and the pixel-defining layer PDL may be covered by the second electrode CE. The second electrode CE may be covered by an upper organic layer CPL.

A filling member FL may be disposed in an inner space defined by a rear surface S-B of a second substrate SUB2, the sealing member SAL, and the display element layer DP-OL. For example, the sealing member SAL may be located in the peripheral region NAA, and may surround the active region AA, with the filling member FL filling a space surrounded by the sealing member SAL. The space may cover the entire active region AA and a portion of the peripheral region NAA.

According to the present embodiment, a recessed portion TC may be defined in the rear surface S-B of the second substrate SUB2. The recessed portion TC may be defined by partially removing the second substrate SUB2 in a direction from the rear surface S-B toward an upper surface facing the rear surface S-B.

The recessed portion TC may overlap the peripheral region NAA. The recessed portion TC may overlap the valley region VA between the partition wall SPC and the sub partition wall SPC-S. Since the recessed portion TC is formed by partially removing the second substrate SUB2, it is possible to ensure a space between the recessed portion TC and the valley region VA in the third direction DR3 to be wider than those of adjacent regions. For example, additional space is created by recessing the second substrate SUB2. A part of the filling member FL may be disposed in the recessed portion TC. In the present embodiment, the recessed portion TC may have a rectangular shape on a cross-section. However, the shape of the recessed portion TC on a cross-section is not limited thereto.

According to the present embodiment, a width WD of the partition wall SPC in the first direction DR1 may be about 10 μm to about 50 μm, and a first thickness TH1 of the partition wall SPC in the third direction DR3 may be about 3 μm to about 5 μm. The width WD and the first thickness TH1 of the partition wall SPC may be respectively greater than a width and a thickness of the sub partition wall SPC-S. In FIG. 6, the dimensions of the partition wall SPC and the sub partition wall SPC-S are enlarged for illustrative purpose.

A second thickness TH2 of the recessed portion TC in the third direction DR3 may be about 5 μm to about 20 μm. A width of the recessed portion TC in the first direction DR1 may be greater than the width WD of the partition wall SPC.

Referring to FIG. 7, on a plane, the recessed portion TC, the partition wall SPC, and the sealing member SAL may be adjacent to the active region AA in this order. That is, the recessed portion TC is the closest one to the active region AA, and the sealing member SAL is the farthest one to the active region AA. The sub partition wall SPC-S may be disposed more adjacent to the active region AA than the recessed portion TC. In the present embodiment, the recessed portion TC, the partition wall SPC, and the sealing member SAL may have a closed line shape.

According to the present inventive concept, since the recessed portion TC overlapping the peripheral region NAA is included in the second substrate SUB2, a time for moving the filling member FL from the active region AA to the peripheral region NAA during curing the sealing member SAL may be delayed. During the curing of the sealing member SAL, the filling member FL may fill the inner space while moving from the active region AA toward the peripheral region NAA between the display element layer DP-OL and the second substrate SUB2. For example, while the first substrate SUB1 and the second substrate SUB2 are attached to each other, the filling member FL may fill the recessed portion TC and the valley region VA via a region between the second substrate SUB2 and the pixel-defining layer PDL and via a region between the second substrate SUB2 and the sub partition wall SPC-S, and then may move toward the sealing member SAL. In FIG. 6, the arrow indicates a moving direction of the filling member FL.

Here, since a region between the recessed portion TC and the valley region VA has a wider space than adjacent regions, a time for moving the filling member FL and a time for filling the space may be delayed. Accordingly, a time for completely curing the sealing member SAL may be ensured, thereby increasing bonding forces among the first substrate SUB1, the circuit element layer DP-CL, and the second substrate SUB2. In other words, the sealing member SAL may be cured before the filling member FL comes into contact with the sealing member SAL, and thus, the sealing member SAL may be prevented from being peeled off, and a bonding force between the display element layer DP-OL and the second substrate SUB2 may be enhanced. Accordingly, a display device EA (see FIG. 1A) with enhanced durability may be provided.

Referring to FIG. 6 again, a sensing panel 220 may be disposed on the second substrate SUB2. The sensing panel 220 may include a plurality of insulating layers IOL, TC-ILL and TC-IL2 and conductive layers MTL1 and MTL2. Each of the conductive layers MTL1 and MTL2 includes a plurality of conductive patterns. The conductive patterns may include a plurality of sensing electrodes SE1 and SE2 (refer to FIG. 5) and a plurality of signal lines SL1, SL2, and SL3 (refer to FIG. 5) respectively connected with the plurality of sensing electrodes SE1 and SE2.

An insulating layer IOL may be disposed on the second substrate SUB2. The insulating layer IOL may include an inorganic insulating layer. At least one insulating layer IOL may be provided on the second substrate SUB2. For example, two inorganic insulating layers IOL may be sequentially stacked on the second substrate SUB2.

A first conductive layer MTL1 may be disposed on the insulating layer IOL. The first insulating layer TC-IL1 may be disposed on the first conductive layer MTL1. The first insulating layer TC-IL1 may be disposed on the insulating layer IOL to cover the first conductive layer MTL1. The first insulating layer TC-IL1 may include an inorganic insulating layer or an organic insulating layer. A second conductive layer MTL2 may be disposed on the first insulating layer TC-ILL The second insulating layer TC-IL2 may be disposed on the second conductive layer MTL2 and the first insulating layer TC-ILL The second insulating layer TC-IL2 may be disposed on the first insulating layer TC-IL1 to cover the second conductive layer MTL2. The second insulating layer TC-IL2 may include an organic insulating layer.

The first conductive layer MTL1 may include bridges BP2 described in FIG. 5, and the bridges BP2 may be connected to corresponding second sensing parts SP2 through contact holes defined in the insulating layer IOL. The second conductive layer MTL2 may include first sensing parts SP1, intermediate parts BP1, and second sensing parts SP2. The second conductive layer MTL2 may include a plurality of mesh lines diagonally extending in each of the first direction DR1 and the second direction DR2, and the mesh lines may overlap the pixel-defining layer PDL and be spaced apart from an opening OP. As the second conductive layer MTL2 is formed of mesh lines, a parasitic capacitance between electrodes of the sensing panel 220 and electrodes included in the display panel 210 may be reduced. Also, since the mesh lines do not overlap the light-emitting region LA (the opening OP) (see FIG. 3), the second conductive layer MTL2 is not viewed by a user of the display device EA.

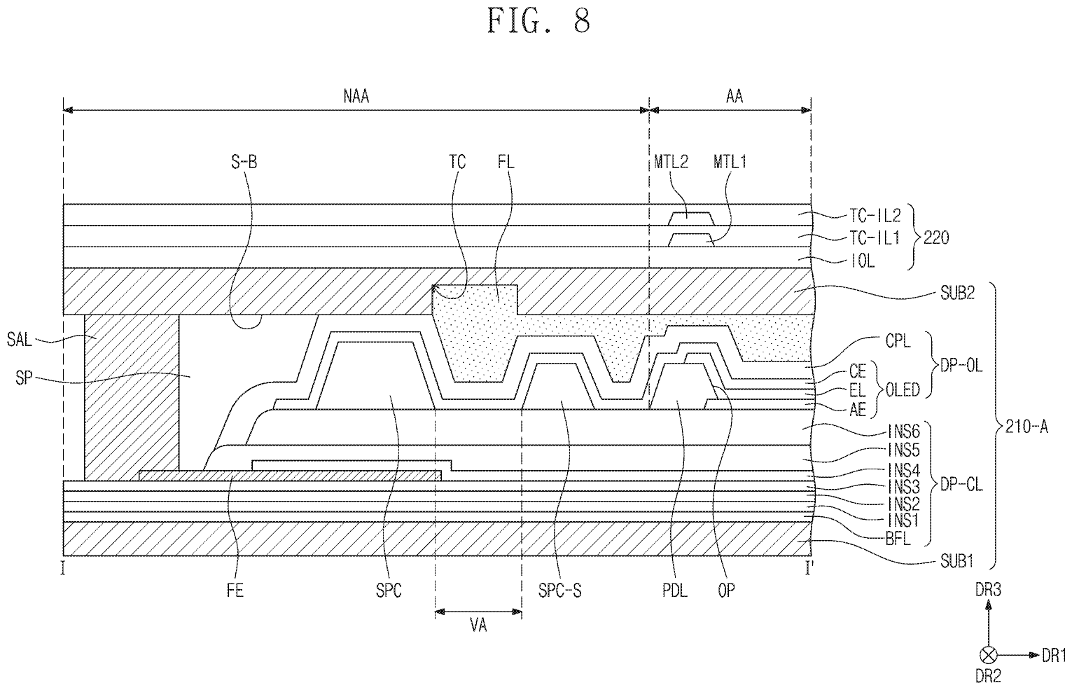

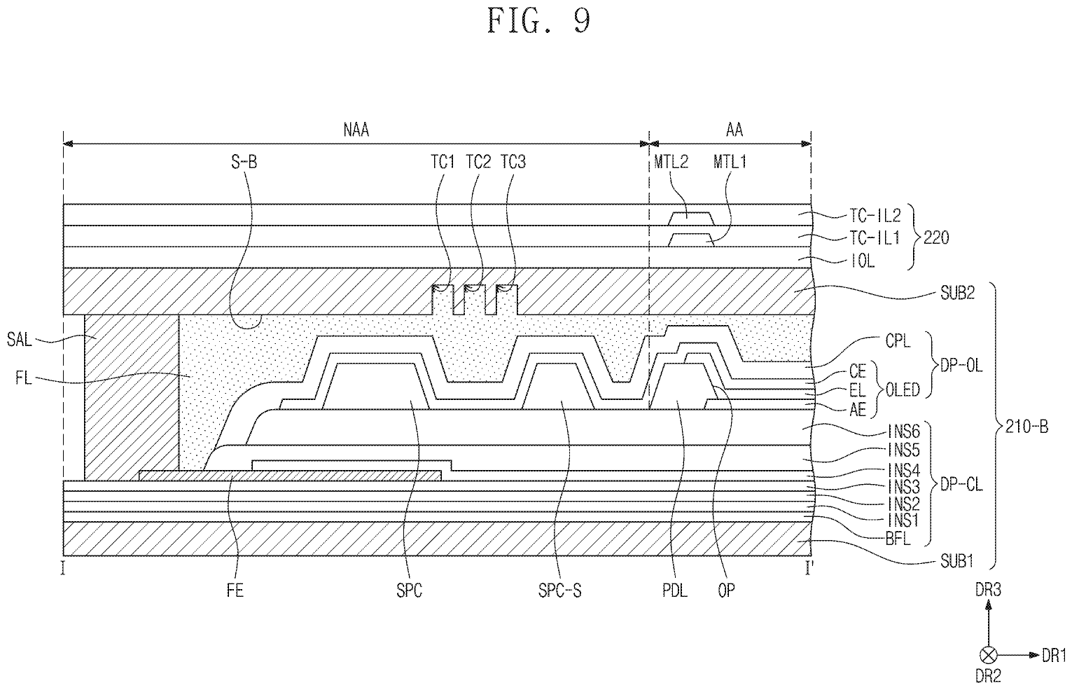

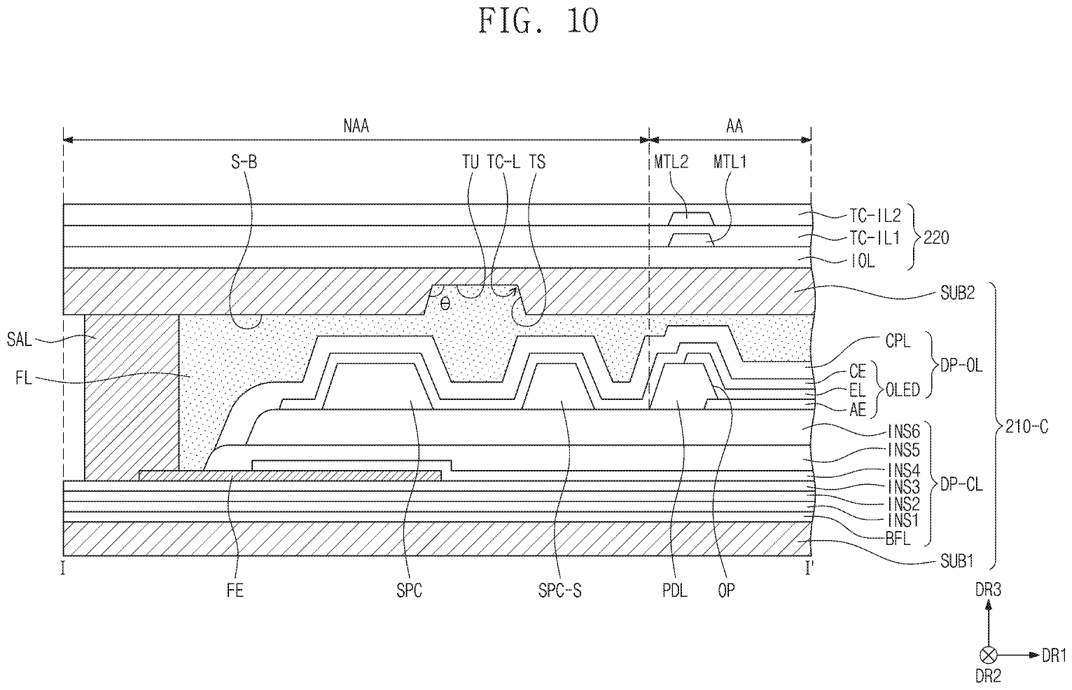

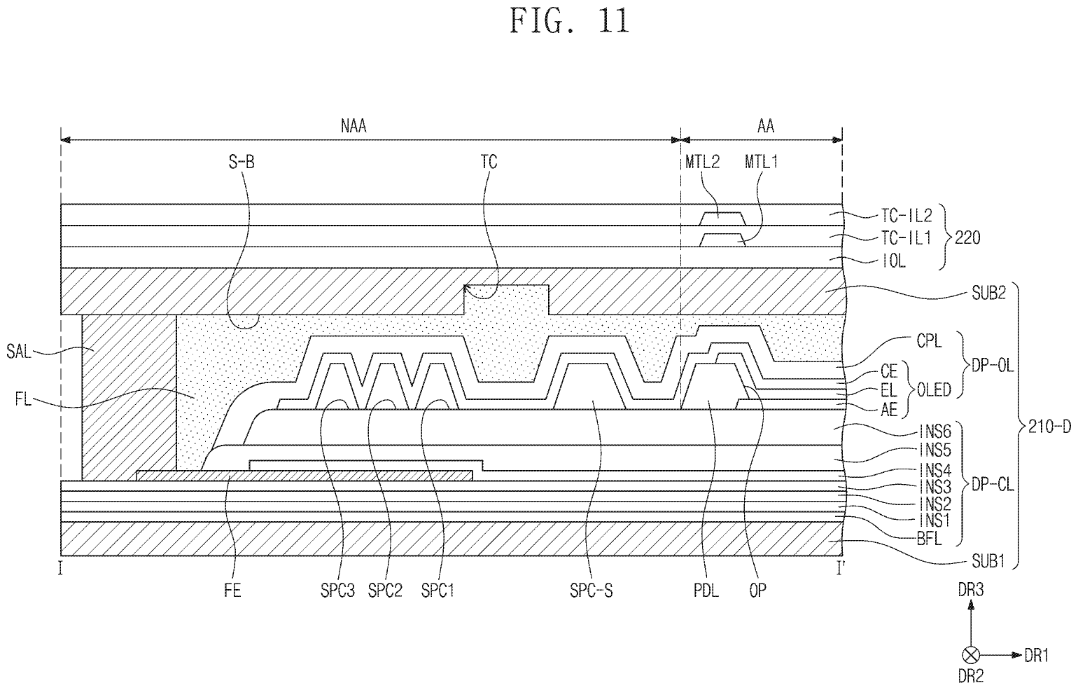

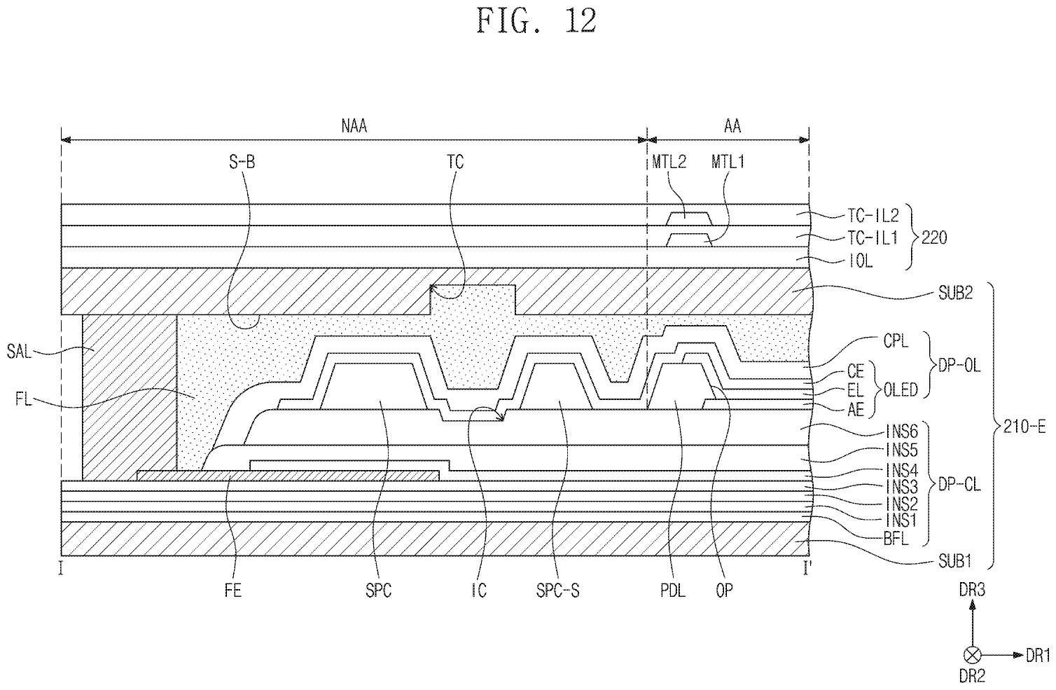

FIG. 8 is a cross-sectional view of a display panel according to an embodiment of the present inventive concept. FIG. 9 is a cross-sectional view of the display panel according to an embodiment of the present inventive concept. FIG. 10 is a cross-sectional view of the display panel according to an embodiment of the present inventive concept. FIG. 11 is a cross-sectional view of the display panel according to an embodiment of the present inventive concept. FIG. 12 is a cross-sectional view of the display panel according to an embodiment of the present inventive concept. The same/similar reference numerals or symbols are used for the same/similar components as those described in FIGS. 1A to 7, and duplicate descriptions therefor will be omitted. FIGS. 8 to 12 may each correspond to a cross-section taken along I-I′ of FIG. 1B.

Referring to FIG. 8, a display panel 210-A according to an embodiment of the present inventive concept may include a first substrate SUB1, a circuit element layer DP-CL, a display element layer DP-OL, and a second substrate SUB2. A sensing panel 220 may be disposed on the second substrate SUB2.

A part overlapping a partition wall SPC of an upper organic layer CPL according to the present embodiment may be in contact with a rear surface S-B of the second substrate SUB2. Accordingly, an empty space SP may be formed between a sealing member SAL and the partition wall SPC.

According to the present embodiment, even when curing of the sealing member SAL is performed, a filling member FL fills only the space between a recessed portion TC and a valley region VA, thereby preventing, in advance, the filling member FL and the sealing member SAL from coming into contact with each other. In other words, the sealing member SAL may be cured without being in contact with the filling member FL, and thus, the sealing member SAL may be prevented from being peeled off, and a bonding force between the display element layer DP-OL and the second substrate SUB2 may be enhanced. Accordingly, a display device EA (see FIG. 1A) with enhanced durability may be provided.

Referring to FIG. 9, a display panel 210-B according to an embodiment may include a first substrate SUB1, a circuit element layer DP-CL, a display element layer DP-OL, and a second substrate SUB2. A sensing panel 220 may be disposed on the second substrate SUB2.

A plurality of first to third recessed portions TC1, TC2, and TC3 may be defined in the second substrate SUB2 according to the present embodiment. The first to third recessed portions TC1, TC2, and TC3 may be disposed far away from an active region AA in this order. That is, the third recessed portion TC3 is the closest one to the active region AA, and the first recessed portion TC1 is the farthest one to the active region AA. The first to third recessed portions TC1, TC2, and TC3 may be spaced apart from each other.

The first to third recessed portions TC1, TC2, and TC3 may be each defined by partially removing the second substrate SUB2 in a direction from a rear surface S-B of the second substrate SUB2 toward an upper surface facing the rear surface S-B. The first to third recessed portions TC1, TC2, and TC3 may each have a closed line shape surrounding the active region AA on a plane. The first recessed portion TC1 may surround the second recessed portion TC2, the second recessed portion TC2 may surround the third recessed portion TC3, and the third recessed portion TC3 may surround the active region AA.

Since regions between the first to third recessed portions TC1, TC2, and TC3 and the valley region VA together have a wider space than adjacent regions, a time for moving the filling member FL and a time for filling the space may be delayed. Thus, the sealing member SAL may be cured before the filling member FL comes into contact with the sealing member SAL, and thus, the sealing member SAL may be prevented from being peeled off, and a bonding force between the display element layer DP-OL and the second substrate SUB2 may be enhanced. Accordingly, a display device EA (see FIG. 1A) with enhanced durability may be provided.

The number of the recessed portions is not limited thereto, may be two or four or more, and is not limited to any one embodiment.

Referring to FIG. 10, a display panel 210-C according to an embodiment of the present inventive concept may include a first substrate SUB1, a circuit element layer DP-CL, a display element layer DP-OL, and a second substrate SUB2. A sensing panel 220 may be disposed on the second substrate SUB2.

A recessed portion TC-L may be defined in the second substrate SUB2 according to the present embodiment. The recessed portion TC-L may be defined by partially removing the second substrate SUB2 in a direction from a rear surface S-B of the second substrate SUB2 toward an upper surface facing the rear surface S-B.

The recessed portion TC-L may be defined by a first inner surface TU parallel to the rear surface S-B and a second inner surface TS connecting the first inner surface TU and the rear surface S-B. The recessed portion TC-L may have a trapezoidal shape on a cross-section. Accordingly, the angle θ between the first inner surface TU and the second inner surface TS may be at least a right angle. For example, the angle θ between the first inner surface TU and the second inner surface TS may be a right angle or an obtuse angle.

Since a region between the recessed portion TC-L and the valley region VA has a wider space than adjacent regions, a time for moving the filling member FL and a time for filling the space may be delayed. Thus, the sealing member SAL may be cured before the filling member FL comes into contact with the sealing member SAL, and thus, the sealing member SAL may be prevented from being peeled off, and a bonding force between the display element layer DP-OL and the second substrate SUB2 may be enhanced. Accordingly, a display device EA (see FIG. 1A) with enhanced durability may be provided.

Referring to FIG. 11, a display panel 210-D according to an embodiment of the present inventive concept may include a first substrate SUB1, a circuit element layer DP-CL, a display element layer DP-OL, and a second substrate SUB2. A sensing panel 220 may be disposed on the second substrate SUB2.

In the present embodiment, the display element layer DP-OL may include a plurality of first to third partition walls SPC1, SPC2, and SPC3. The first to third partition walls SPC1, SPC2, and SPC3 may be arranged spaced apart from each other in a direction far away from the active region AA. The number of the partition walls is not limited thereto, may be two or four or more, and is not limited to any one embodiment. The first to third partition walls SPC1, SPC2, and SPC3 may be disposed adjacent to an active region AA in this order. That is, the first partition wall SPC1 is the closest one to the active region AA, and the third partition wall SPC3 is the farthest one to the active region AA. The first to third partition walls SPC1, SPC2, and SPC3 may be disposed on a sixth insulating layer INS6, and may include a material the same as that of the pixel-defining layer PDL. The first to third partition walls SPC1, SPC2, and SPC3 may be each covered by the second electrode CE. According to the present embodiment, similar to that illustrated in FIG. 6, a recessed portion TC may be defined in the rear surface S-B of the second substrate SUB2. Accordingly, similar to that described above with reference to FIG. 6, a display device EA (see FIG. 1A) with enhanced durability may be provided using the structure features of the present embodiment.

Referring to FIG. 12, a display panel 210-E according to an embodiment of the present inventive concept may include a first substrate SUB1, a circuit element layer DP-CL, a display element layer DP-OL, and a second substrate SUB2. A sensing panel 220 may be disposed on the second substrate SUB2.

In the present embodiment, a pattern portion IC may be defined in a sixth insulating layer INS6 of the display element layer DP-OL. The pattern portion IC may be formed by partially removing the sixth insulating layer INS6 in a thickness direction. Among the first to sixth insulating layers INS1 to INS6, the sixth insulating layer INS6 is in contact with the partition wall SPC and the second electrode CE. The sixth insulating layer INS6 may be partially removed from its front surface facing the second substrate SUB2 to form the pattern portion IC. The pattern portion IC may be disposed between a partition wall SPC and a sub partition wall SPC-S, and overlap a recessed portion TC. Accordingly, it is possible to ensure a space between the recessed portion TC and the pattern portion IC in the third direction DR3 to be wider than those of adjacent regions.

Since a region between the recessed portion TC and the pattern portion IC has a wider space than adjacent regions, a time for moving the filling member FL and a time for filling the space may be delayed. Thus, the sealing member SAL may be cured before the filling member FL comes into contact with the sealing member SAL, and thus, the sealing member SAL may be prevented from being peeled off, and a bonding force between the display element layer DP-OL and the second substrate SUB2 may be enhanced. Accordingly, a display device EA (see FIG. 1A) with enhanced durability may be provided.

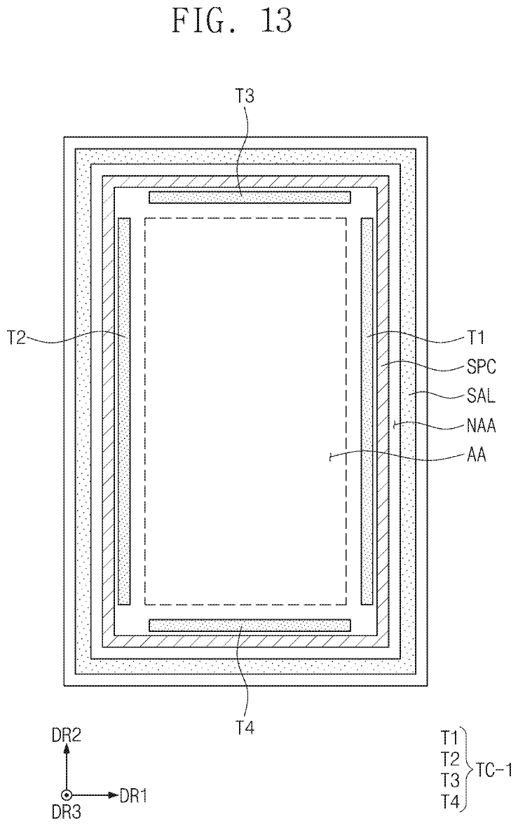

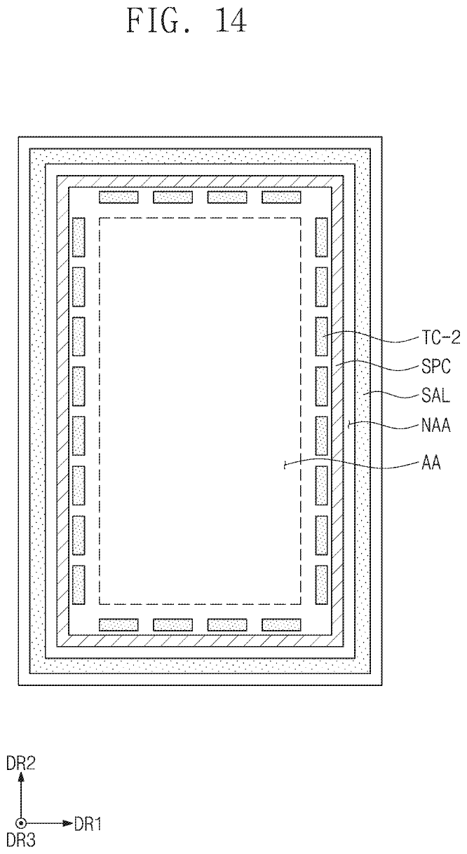

FIG. 13 is a plan view illustrating an arrangement relationship of a recessed portion, a partition wall, and a sealing member according to an embodiment of the present inventive concept. FIG. 14 is a plan view illustrating an arrangement relationship of the recessed portion, the partition wall, and the sealing member according to an embodiment of the present inventive concept. The same/similar reference numerals or symbols are used for the same/similar components as those described in FIGS. 1A to 7, and duplicate descriptions therefor will be omitted.

Referring to FIG. 13, a recessed portion TC-1, a partition wall SPC, and a sealing member SAL may be adjacent to an active region AA in this order on a plane. That is, the recessed portion TC-1 is the closest one to the active region AA, and the sealing member SAL is the farthest one to the active region AA.

In the present embodiment, the recessed portion TC-1 may include a plurality of first to fourth patterns T1, T2, T3, and T4. A first pattern T1 and a second pattern T2 may each extend in the second direction DR2, and may be spaced apart from each other along the first direction DR1 with the active region AA therebetween. The first pattern T1 and the second pattern T2 may be defined as “long-side patterns”.

A third pattern T3 and a fourth pattern T4 may each extend in the first direction DR1, and may be spaced apart from each other along the second direction DR2 with the active region AA therebetween. The third pattern T3 and the fourth pattern T4 may be defined as “short-side patterns”.

In the present embodiment, the first to fourth patterns T1, T2, T3, and T4 may be spaced apart from each other. For example, the first to fourth patterns T1, T2, T3, and T4 may each extend along corresponding long sides and short sides of the active region AA, and may be spaced apart from each other at corners of the active region AA.

Since a region between the recessed portion TC-1 and the valley region VA has a wider space than adjacent regions, a time for moving the filling member FL and a time for filling the space may be delayed. Thus, the sealing member SAL may be cured before the filling member FL comes into contact with the sealing member SAL, and thus, the sealing member SAL may be prevented from being peeled off, and a bonding force between the display element layer DP-OL and the second substrate SUB2 may be enhanced. Accordingly, a display device EA (see FIG. 1A) with enhanced durability may be provided.

Referring to FIG. 14, recessed portions TC-2, a partition wall SPC, and a sealing member SAL may be adjacent to an active region AA in this order on a plane. That is, the recessed portions TC-2 are the closest ones to the active region AA, and the sealing member SAL is the farthest one to the active region AA.

In the present embodiment, the recessed portions TC-2 may be disposed spaced apart from each other along the first direction DR1 and the second direction DR2. The recessed portions TC-2 may be spaced apart from each other while surrounding the active region AA. The recessed portions TC-2 may also be described as a plurality of patterns of a recessed portion, and the patterns are arranged spaced apart from each other while surrounding the active region AA.

Since a region between the recessed portions TC-2 and the valley region VA has a wider space than adjacent regions, a time for moving the filling member FL and a time for filling the space may be delayed. Thus, the sealing member SAL may be cured before the filling member FL comes into contact with the sealing member SAL, and thus, the sealing member SAL may be prevented from being peeled off, and a bonding force between the display element layer DP-OL and the second substrate SUB2 may be enhanced. Accordingly, a display device EA (see FIG. 1A) with enhanced durability may be provided.

According to an embodiment of the present inventive concept, since a structure capable of delaying a time for moving a filling member is included, a time for completely curing a sealing member may be ensured, and thus a bonding force between substrates may be increased. Accordingly, a display device with enhanced durability may be provided.

In the above, description has been made with reference to preferred embodiments of the present inventive concept, but those skilled in the art may understand that various modifications and changes may be made therein without departing from the spirit and scope of the present inventive concept as defined in the appended claims.

What is claimed is:

1. A display device comprising:
a first substrate including an active region and a peripheral region adjacent to the active region;
a circuit element layer disposed on the first substrate and including a plurality of insulating layers and at least one transistor;
a display element layer disposed on the circuit element layer and including:
a pixel-defining layer having an opening defined therein, and overlapping the active region;
a light-emitting element including a first electrode at least partially exposed by the opening, a second electrode, and a light-emitting layer disposed between the first and second electrodes; and
a partition wall overlapping the peripheral region;
a second substrate disposed on the display element layer;
a sealing member disposed between the circuit element layer and the second substrate to define an inner space, and overlapping the peripheral region; and
a filling member disposed in the inner space,
wherein a recessed portion overlapping the peripheral region is defined in a rear surface of the second substrate facing the display element layer, and
a part of the filling member is disposed in the recessed portion.

2. The display device of claim 1, wherein on a plane, the recessed portion, the partition wall, and the sealing member are adjacent to the active region in this order.

3. The display device of claim 1, wherein the second electrode overlaps the active region and the peripheral region, and covers the partition wall.

4. The display device of claim 3, further comprising an upper organic layer disposed on the second electrode, and overlapping the active region and the peripheral region,
wherein the upper organic layer is in contact with the filling member.

5. The display device of claim 4, wherein a part of the upper organic layer overlapping the partition wall is in contact with the rear surface of the second substrate.

6. The display device of claim 1, wherein the recessed portion is provided in plurality, and the recessed portions are arranged spaced apart from each other in a direction far away from the active region.

7. The display device of claim 1, wherein the recessed portion is defined by a first inner surface parallel to the rear surface of the second substrate and a second inner surface connecting the first inner surface and the rear surface of the second substrate, and
an angle between the first inner surface and the second inner surface is at least a right angle.

8. The display device of claim 1, wherein the partition wall is provided in plurality, and the partition walls are arranged spaced apart from each other in a direction far away from the active region.

9. The display device of claim 1, wherein in an insulating layer contacting the partition wall and the second electrode among the insulating layers, a pattern portion, which is obtained by partially removing the insulating layer contacting the partition wall and the second electrode from a front surface facing the second substrate, and overlaps the recessed portion, is defined.

10. The display device of claim 1, further comprising a sub partition wall disposed between the pixel-defining layer and the partition wall, and overlapping the peripheral region,
wherein a valley region between the partition wall and the sub partition wall overlaps the recessed portion.

11. The display device of claim 1, wherein the recessed portion has, on a plane, a closed line shape surrounding the active region.

12. The display device of claim 1, wherein, on a plane, the recessed portion comprises short-side patterns extending in a first direction, and spaced apart from each other in a second direction crossing the first direction with the active region therebetween, and long-side patterns extending in the second direction, and spaced apart from each other in the first direction with the active region therebetween, and
the short-side patterns and the long-side patterns are spaced apart from each other at corners of the active region.

13. The display device of claim 1, wherein the recessed portion comprises a plurality of patterns, and the patterns are arranged spaced apart from each other while surrounding the active region.

14. The display device of claim 1, wherein the recessed portion has a thickness of about 5 μm to about 20 μm.

15. The display device of claim 1, wherein the partition wall has a thickness of about 3 μm to about 5 μm,
a width of the partition wall in one direction is about 10 μm to about 50 μm, and
a width of the recessed portion in the one direction is greater than the width of the partition wall.

16. The display device of claim 1, wherein the sealing member comprises any one among silicone, epoxy, and an acryl-based thermosetting material, and has a viscosity of about 3000 cps to about 40000 cps.

17. The display device of claim 1, further comprising a floating pattern disposed on a layer the same as that of one of electrodes included in a transistor and overlapping the peripheral region,
wherein the floating pattern is in contact with the sealing member.

18. A display device comprising:
a first substrate including an active region and a peripheral region adjacent to the active region;
a plurality of insulating layers disposed on the first substrate;
a pixel-defining layer having an opening defined therein, and overlapping the active region;
a partition wall disposed on a layer the same as that of the pixel-defining layer, and overlapping the peripheral region;
a light-emitting element disposed on the first substrate and including a first electrode at least partially exposed by the opening, a second electrode, and a light-emitting layer disposed between the first and second electrodes;
a second substrate disposed on the light-emitting element and having therein a recessed portion overlapping the peripheral region;
a sealing member overlapping the peripheral region, and disposed between one of the insulating layers and the second substrate to define an inner space; and
a filling member disposed in the inner space,
wherein on a plane, the recessed portion, the partition wall, and the sealing member are adjacent to the active region in this order.

19. The display device of claim 18, wherein the recessed portion has, on a plane, a closed line shape surrounding the active region.

20. The display device of claim 18, wherein the recessed portion has, on a cross-section, a trapezoidal shape.
